(19) United States
(12) Patent Application Publication
(10) Pub. No.: US 2013/0307523 A1
(43) Pub. Date: Nov. 21, 2013

(54) ANALOG UNIT OF SEQUENCER SYSTEM

(71) Applicants: Satoshi Aoki, Tokyo (JP); Hirokazu Nomoto, Tokyo (JP); Tetsuya Tanaka, Tokyo (JP)

(72) Inventors: Satoshi Aoki, Tokyo (JP); Hirokazu Nomoto, Tokyo (JP); Tetsuya Tanaka, Tokyo (JP)

(73) Assignee: MItsubishi Electric Corporation, Chiyoda-ku, Tokyo (JP)

(21) Appl. No.: 13/982,347

(22) PCT Filed: Feb. 3, 2011
(86) PCT No.: PCT/JP2011/052288

§ 371 Date: Jul. 29, 2013

(51) Int. Cl. G01R 19/165

(52) U.S. Cl. CPC G01R 19/16528
USPC 324/76.12

(57) ABSTRACT

An analog unit having a multiple-channel configuration among analog units included in a sequencer system is such that an AC signal as a measurement target, which is captured by a CT sensor, can be directly input to each of a plurality of channels, and the analog unit includes a setting unit that sets, in an internal memory, an abnormality-determination peak current value and an abnormal peak current duration, which are applied to the AC signal as a measurement target, for each of the channels, and a detecting unit that, when the AC signal as a measurement target includes an AC signal that maintains a state where a peak value exceeds the abnormality-determination peak current value for the abnormal peak current duration, detects generation of an abnormal alternating current in each of the channels.

### FIELD

The present invention relates to an analog unit of a sequencer system.

### BACKGROUND

Sequencer systems are known that use a system in which an AC signal that is input/output from a device is digitalized by inputting the AC signal to a signal converter via a current transformer (hereinafter, referred to as a “CT sensor”) and the AC signal then is input to the analog unit. Such a system is a configuration in which an AC signal that is input/output by a device of process is captured for an analog unit.

For example, if the load on a motor changes due to consumption or wear of the components, such as the gears, in a device driven by the motor, the motor current transiently increases at the time of start-up. Therefore, an abnormal alternating current, which has and maintains a high peak value, is generated.

A user of a sequencer system performs maintenance management and failure diagnosis on devices on the basis of the information on the devices that is detected by the sequencer system. Therefore, in the sequencer system, it is important to detect whether an abnormal alternating current, which is transiently generated when the system is started or when the devices are overloaded and which has and maintains a high peak value, is generated as maintenance information to be provided to the user. Moreover, the number of times an abnormal alternating current is generated is also important maintenance information that needs to be provided to the user. The maintenance information needs to be detected in the analog unit.

### CITATION LIST

### Patent Literature

Patent Literature 1: Japanese Patent Application Laid-open No. 2001-16759

Patent Literature 2: Japanese Patent Application Laid-open No. 2008-61450

Patent Literature 3: Japanese Patent Application Laid-open No. 11-262165

### SUMMARY

### Technical Problem

However, conventional analog units, to which an AC signal measured by a CT senor is input after being digitalized, do not have a function of detecting the generation of an abnormal alternating current, which has and maintains a high peak value, and therefore conventional analog units cannot detect the number of times an abnormal alternating current is generated.

Thus, conventionally, it is necessary to separately construct a sequencer system that can, from an AC signal measured by a CT sensor, detect the generation of an abnormal alternating current, which has and maintains a high peak value, and thus can detect the number of times it is generated.

Patent Literature 1 discloses a configuration in which the load current of household electrical appliances is captured as digital values by a CT sensor and an A/D converter circuit and the maximum value of the digital values is read and stored.

Moreover, Patent Literature 2 discloses a configuration in which the peak value of the motor current in each cycle of an AC power source is detected and stored in a memory unit.

Furthermore, Patent Literature 3 discloses a configuration in which analog current measured by CT sensors is transmitted to a PLC via an analog input board connected to the bus of the PLC (programmable controller) and a configuration in which protective relays that can monitor current at high speed are connected to the PLC bus.

The present invention is achieved in view of the above and has an object to obtain an analog unit of a sequencer system that is capable of detecting the generation of an abnormal alternating current and detecting the number of times an abnormal alternating current is generated from an AC signal as a measurement target, which is captured by a CT sensor, in each of a plurality of channels.

### Solution to Problem

To solve the above problems and achieve the object, according to an aspect of the present invention, an analog unit of a sequencer system, an analog unit having a multiple-channel configuration among analog units included in a sequencer system is such that an AC signal as a measurement target, which is captured by a CT sensor, is capable of being directly input to each of a plurality of channels. The analog unit includes: a setting unit that sets, in an internal memory, an abnormality-determination peak current value and an abnormal peak current duration, which are applied to the AC signal as a measurement target, for each of the channels; and a detecting unit that, when the AC signal as a measurement target includes an AC signal that maintains a state where a peak value exceeds the abnormality-determination peak current value for the abnormal peak current duration, detects generation of an abnormal alternating current in each of the channels.

### Advantageous Effects of Invention

According to the present invention, the abnormality-determination peak current value and the abnormal peak current duration are prepared as data with which the presence or absence of the generation of an abnormal alternating current is determined and an AC signal as a measurement target, which is captured by a CT sensor, is monitored while being compared with the abnormality-determination peak current value and the abnormal peak current duration. Therefore, an effect can be obtained where it is possible to detect the generation of an abnormal alternating current, which is transiently generated when the system is started or the devices are overloaded and which has and maintains a high peak value.

### BRIEF DESCRIPTION OF DRAWINGS

FIG. 1 is a block diagram illustrating the overall configuration of a sequencer system according to one embodiment of the present invention.

FIG. 2 is a diagram illustrating the connection relationship between an analog unit having a multiple-channel configuration and CT sensors.

FIG. 3 is a conceptual diagram explaining a configuration and operation for detecting the generation of an abnormal alternating current.

FIG. 4 is a flowchart explaining the detection operation for detecting an abnormal alternating current and the detection operation for detecting the number of times an abnormal alternating current is generated.

### DESCRIPTION OF EMBODIMENTS

An embodiment of an analog unit of a sequencer system according to the present invention will be described in detail below with reference to the drawings. This invention is not limited to this embodiment.

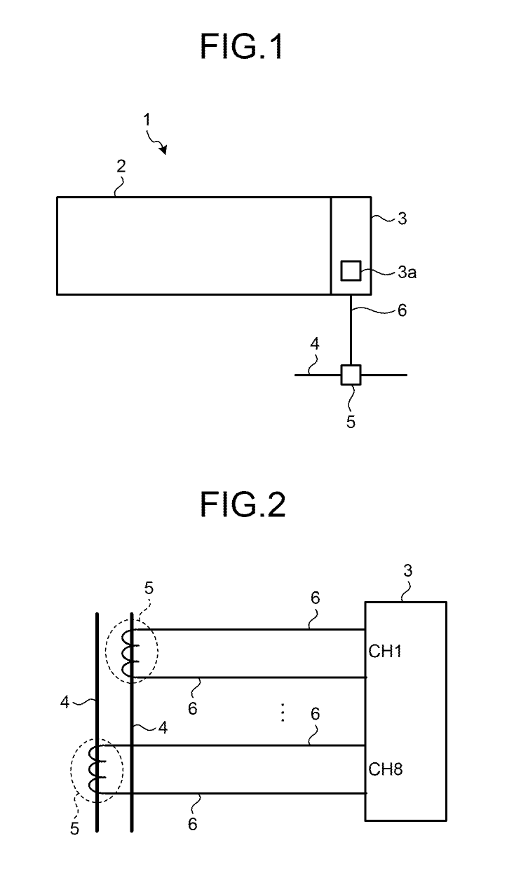

FIG. 1 is a block diagram illustrating the overall configuration of a sequencer system according to one embodiment of the present invention. FIG. 2 is a diagram illustrating the connection relationship between an analog unit having a multiple-channel configuration and CT sensors.

In FIG. 1, a sequencer system 1 includes a sequencer unit 2 that executes a ladder program that controls a device of process and an analog unit 3 that captures input/output analog signals, which the sequencer unit 2 needs, from the device of process. In this embodiment, among the analog signals that are input/output by the device of process, an AC signal is picked up.

Specifically, an AC signal that is input/output by the device of process flows in an AC line 4. FIG. 1 illustrates a configuration in which an AC signal measured by a CT sensor 5, which is arranged on the AC line 4, is directly input via a connection cable 6. Such a configuration is a configuration for capturing, for the analog unit 3, an AC signal input/output by the device of process.

The sequencer unit 2 is provided with a plurality of the analog units 3 that include one having a multiple-channel configuration. As illustrated in FIG. 2, the analog unit 3 having a multiple-channel configuration, for example, has an eight-channel (CH1 to CH8) configuration. The CT sensors 5, which are arranged on the AC lines 4 on a one-to-one basis, are connected to the input ports of the channels via the connection cables 6. The AC lines 4 are wired for the input ports of the channels, respectively.

In each channel, the analog unit 3 having an eight-channel configuration illustrated in FIG. 2 has a function of: detecting the generation of an abnormal alternating current and the number of times it is generated by using an AC signal measured by the CT sensor 5; and storing, in an internal memory 3a, the fact that the generation is detected and the number of times it is generated.

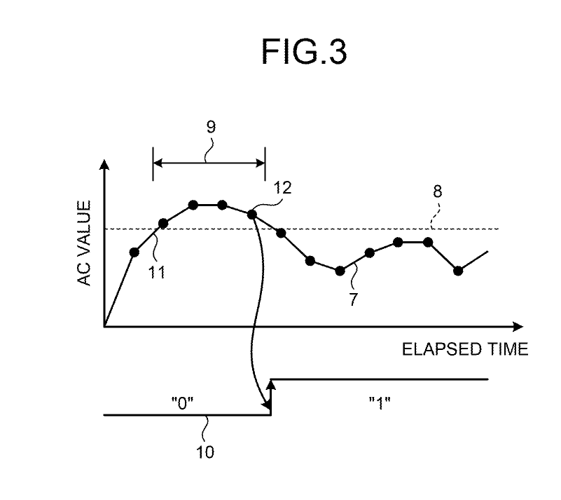

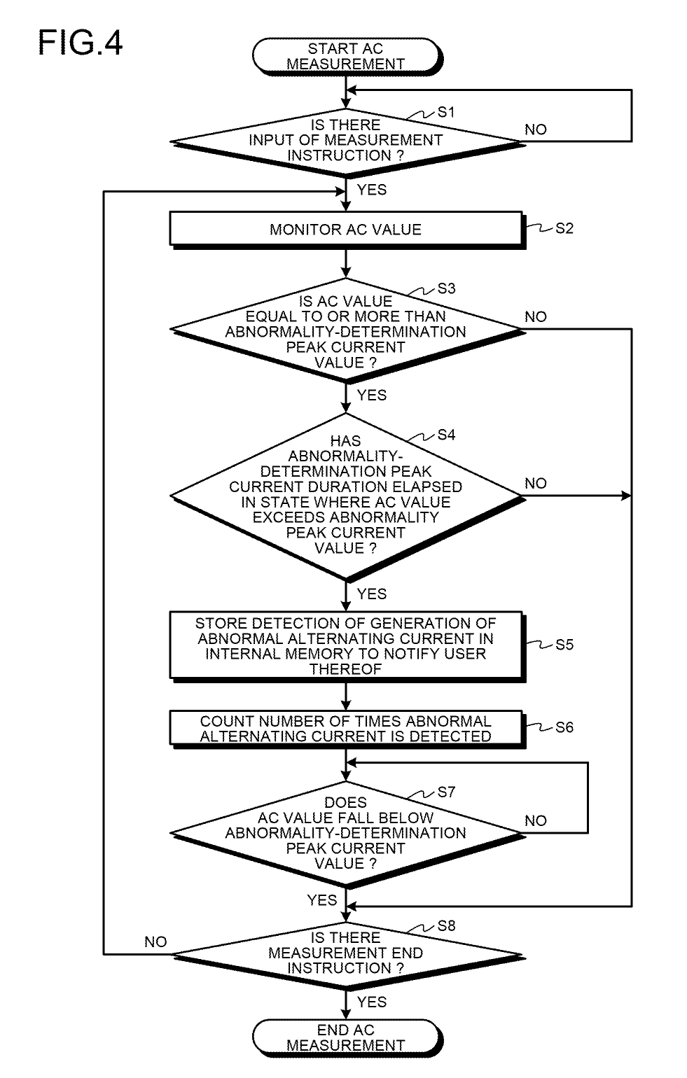

A concrete explanation will be made with reference to FIG. 3 and FIG. 4. FIG. 3 is a conceptual diagram explaining a configuration and operation for detecting the generation of an abnormal alternating current. FIG. 4 is a flowchart explaining the detection operation for detecting an abnormal alternating current and the detection operation for detecting the number of times an abnormal alternating current is generated.

In FIG. 3, the vertical axis indicates the AC value obtained by the effective value calculation and the horizontal axis indicates the elapsed time after the system is started. The timings at the black circles plotted at regular intervals are end/start timings of the effective value calculation by which the AC value is calculated from an AC signal measured by the CT sensor 5. The CPU (not illustrated) of the analog unit 3 recognizes, as an AC signal measured by the CT sensor 5, an AC signal 7 illustrated by a locus obtained by connecting the calculated AC values at the calculation end/start timings. In other words, the AC value, which is an amplitude value of the AC signal 7, is a monitoring target.

In the internal memory 3a of the analog unit 3, an abnormality-determination peak current value 8 with respect to the AC value calculated by the effective value calculation and an abnormal peak current duration 9 with respect to the AC signal 7 are set for each channel. A user can set the abnormality-determination peak current value 8 and the abnormal peak current duration 9. Moreover, for each channel, the internal memory 3a is provided with: a detection output flag 10, which indicates the fact that the generation is detected; and a number-of-detection counting unit, which stores the number of times an abnormal alternating current is detected.

Detection of the generation of an abnormal alternating current is performed by comparing the calculated AC value with the abnormality-determination peak current value 8 at each calculation end/start timing. If the AC value calculated at a certain calculation end/start timing has already exceeded the abnormality-determination peak current value 8, the start time of the abnormal peak current duration 9 is set in the timer at a timing 11, which is in accordance with this difference, and the timer is started. Thereafter, if the calculated AC value becomes equal to or less than the abnormality-determination peak current value 8 within the timer period (the abnormal peak current duration 9), the timer is reset. In other words, the detection output flag 10 of a corresponding channel prepared in the internal memory 3a is maintained at “0” level (absence of detection of the generation).

In contrast, as illustrated in FIG. 3, if the state where the calculated AC value continuously exceeds the abnormality-determination peak current value 8 is maintained for the timer period (the abnormal peak current duration 9), the detection output flag 10 is raised to “1” level (presence of detection of the generation) from “0” level (absence of detection of the generation) in response to a calculation end/start timing 12 immediately before the lapse of the timer period (the abnormal peak current duration 9). Then, the value 1 is set in the number-of-detection counting unit of the corresponding channel prepared in the internal memory 3a.

In FIG. 3, the AC signal 7 changes in a state below the abnormality-determination peak current value 8 after the timing that follows the calculation end/start timing 12. In this process, if an abnormal alternating current, whose peak value (calculated AC value) is maintained in a state of continuously exceeding the abnormality-determination peak current value 8 for the abnormal peak current duration 9, is generated in the AC signal 7, the set/reset operation of the detection output flag 10 and the count operation by the number-of-detection counting unit in the internal memory 3a are performed each time such an abnormal alternating current is generated.

The software of a user always accesses the internal memory 3a of the analog unit 3; therefore, the user can instantaneously recognize the generation of an abnormal alternating current detected by the analog unit 3 as described above. In other words, the analog unit 3 is configured to be capable of instantaneously notifying a user of the generation of a detected abnormal alternating current. The number of times of detection can also be used by the software of a user in a similar manner.

Next, in FIG. 4, the CPU in the analog unit 3 waits for an input of the measurement instruction to measure the alternating current (Step S1). When the measurement instruction is input (Yes in Step S1), the calculated AC value is monitored (Step S2) and it is determined whether the calculated AC value is equal to or more than the abnormality-determination peak current value 8 (Step S3).

In Step S3, if the calculated AC value is equal to or less than the abnormality-determination peak current value 8 (No in Step S3), the process proceeds to Step S8 and the presence or absence of the measurement end instruction is checked. In contrast, if the calculated AC value exceeds the abnormality-determination peak current value 8 (Yes in Step S3), then, in Step S4, it is determined whether the abnormal peak current duration 9 has elapsed in a state where the calculated AC value exceeds the abnormality-determination peak current value 8.

In Step S4, if the calculated AC value falls below the abnormality-determination peak current value 8 before the abnormal peak current duration 9 has elapsed, the generation of an abnormal alternating current is not detected; therefore, a negative determination is made (No in Step S4). Then, the process proceeds to Step S8 while maintaining the detection output flag 10 at “0” and the presence or absence of an input of the measurement end instruction is checked. In contrast, if the calculated AC value still exceeds the abnormality-determination peak current value 8 after the abnormal peak current duration 9 has elapsed, the generation of an abnormal alternating current is detected; therefore, a positive determination is made (Yes in Step S4) and the processes (notification process of notifying a user) in Step S5 and Step S6 are performed.

In Step S5, detection of the generation of an abnormal alternating current is stored in the internal memory 3a to notify a user thereof (the detection output flag 10=“1”). in Step S6, the number of times an abnormal alternating current is generated is counted and is stored in the internal memory 3a. Then, it is confirmed that the calculated AC value falls below the abnormality-determination peak current value 8 (Yes in Step S7). Then, the process proceeds to Step S8 and the presence or absence of an input of the measurement end instruction is checked.

The processes in Step S2 to Step S7 are repeatedly performed until the measurement end instruction is input (No in Step S8). When the measurement end instruction is input (Yes in Step S8), measurement of the alternating current ends.

As described above, the analog unit 3 of the sequencer system according to this embodiment prepares the abnormality-determination peak current value 8 and the abnormal peak current duration 9 as data with which the presence or absence of the generation of an abnormal alternating current is determined and monitors an AC signal as a measurement target, which is captured by the CT sensor 5, while comparing it with the abnormality-determination peak current value 8 and the abnormal peak current duration 9. Therefore, it is possible to detect the generation of an abnormal alternating current, which is transiently generated when the system is started or the devices are overloaded and which has and maintains a high peak value. Moreover, the number of times it is generated can be detected.

At this point, if the generation of an abnormal alternating current is detected, it is stored in the internal memory 3a so that a user can instantaneously recognize the fact that the generation is detected. Moreover, the detected number of times an abnormal alternating current is generated is stored in the internal memory 3a so that a user can use it.

A user can arbitrarily set the abnormality-determination peak current value 8 and the abnormal peak current duration 9 that are used when the generation of an abnormal alternating current is detected; therefore, the user can detect the generation of an abnormal alternating current, which is adapted for the user's own sequencer system, and detect the number of times it is generated.

Thus, a user can appropriately perform failure diagnosis on a measurement target device and maintenance management of devices. Because the number of times an abnormal alternating current is generated, which indicates the operational history of a device, is stored in the internal memory 3a, a user can easily construct an instrumentation monitoring system, which monitors alternating current by using the CT sensors 5, in the user's own sequencer system.

### INDUSTRIAL APPLICABILITY

As described above, the analog unit of the sequencer system according to the present invention is useful as an analog unit of a sequencer system that is capable of detecting the generation of an abnormal alternating current and the number of times it is generated by using an AC signal as a measurement target, which is captured by a CT sensor for each of a plurality of channels.

### REFERENCE SIGNS LIST

1 sequencer system
2 sequencer unit
3 analog unit
3a internal memory
4 AC line
5 current transformer (CT sensor)
6 connection cable
7 AC signal
8 abnormality-determination peak current value
9 abnormal peak current duration
10 detection output flag
11 start timing of abnormal peak current duration
12 calculation end/start timing immediately before the lapse of abnormal peak current duration

1.-4. (canceled)

5. An analog unit of a sequencer system, comprising:
a multiple-channel configuration analog unit among analog units included in the sequencer system, wherein
the multiple-channel configuration analog unit is configured to directly input an AC signal as a measurement target to each of a plurality of channels;
a setting unit that sets, in an internal memory, an abnormality-determination peak current value and an abnormal peak current duration, which are applied to the AC signal as a measurement target, for each of the channels; and
a detecting unit that, when the AC signal as a measurement target includes an AC signal that maintains a state where a peak value exceeds the abnormality-determination peak current value for the abnormal peak current duration, detects generation of an abnormal alternating current in each of the channels, wherein
when a user sets and inputs the abnormality-determination peak current value and the abnormal peak current duration for each of the channels, the setting unit stores, in the internal memory, the abnormality-determination peak current value and the abnormal peak current duration that are input, wherein
the detecting unit is configured to:
set a detection output flag to an abnormal level at a timing when the duration of a state where the AC signal exceeds the abnormality-determination peak current value elapses the abnormal peak current duration or more; and
set the detection output flag to a normal level at a timing, after the AC signal exceeds the abnormality-determination peak current value, when the AC signal becomes equal to or less than the abnormality-determination peak current value within the abnormal peak current duration.

6. The analog unit of a sequencer system according to claim 5, wherein when a user sets and inputs the abnormality-determination peak current value and the abnormal peak current duration for each of the channels, the setting unit stores, in the internal memory, the abnormality-determination peak current value and the abnormal peak current duration that are input.

7. The analog unit of a sequencer system according to claim 5, wherein when the detecting unit detects generation of the abnormal alternating current in each of the channels, the detecting unit stores, in the internal memory, a fact that generation of the abnormal alternating current is detected.
